(19) United States
(12) Patent Application Publication
(10) Pub. No.: US 2017/0250317 A1
(43) Pub. Date: Aug. 31, 2017

(54) PHOTOELECTRIC SEMICONDUCTOR DEVICE

(71) Applicants: LITE-ON OPTO TECHNOLOGY (CHANGZHOU) CO., LTD., CHANGZHOU (CN); LITE-ON TECHNOLOGY CORPORATION, TAIPEI CITY (TW)

(72) Inventors: YI-HSUAN CHEN, NEW TAIPEI CITY (TW); SHIH-CHANG HSU, TAIPEI CITY (TW)

(21) Appl. No.: 15/214,391

(22) Filed: Jul. 19, 2016

(30) Foreign Application Priority Data
Feb. 26, 2016 (CN) 201610109502.7

(51) Int. Cl. H01L 33/50; H01L 33/56; H01L 33/60

(52) U.S. Cl. CPC H01L 33/502; H01L 33/60; H01L 33/56

(57) ABSTRACT

The instant disclosure provides a photoelectric semiconductor device including a substrate, a light-emitting diode chip, a converting material, an encapsulant, and a protective layer. The light-emitting diode chip is arranged on the substrate. The encapsulant has a Shore hardness of higher than D50 or a moisture-permeable value of less than 10 g/m²·24 hrs, and the converting material includes a first wavelength converting compound having a main peak wavelength in green spectrum and a second wavelength converting compound having a main peak wavelength in red spectrum which are fluorescent materials having a FWHM of equal to or less than 50 nm. The photoelectric semiconductor device provided by the instant disclosure exhibits improved NTSC, brightness and reliability.

### BACKGROUND

1. Technical Field

The instant disclosure relates to a photoelectric semiconductor device, in particular, to a photoelectric semiconductor device with improved NTSC, brightness and reliability.

2. Description of Related Art

White light emitting diodes (LED) have been widely used as the back light source for displays. Generally, the white emitting diodes for a back light source must be used in conjunction with color filters to fulfill the requirement of high NTSC. However, under this circumstance, the existing white LED for the back light source has an NTSC value of about 72%. Although the NTSC value can be improved by using commercial phosphors, the brightness of the white LED is deleteriously affected. For instance, using a fluorescent material comprising a yellow nitride and a red nitride of 620 nanometers can achieve a NTSC value of about 72% and a brightness of 100%. Upon substituting the yellow nitride with a green β-SiAlON phosphor and substituting the red nitride of 620 nanometers with a red nitride of 660 nanometers, the NTSC value is increased to about 85%, but the brightness is significantly decreased to about 65%. In addition, in a process involving the use of different converting materials (wavelength converting material) such as phosphors (or fluorescent material) to improve the optical properties of the white LED, there is a problem regarding reduction of the reliability of the photoelectric semiconductor device.

Accordingly, there is a need for enhancing the NTSC value of the photoelectric semiconductor device while ensuring the quality of brightness and reliability thereof.

### SUMMARY

In order to overcome the above technical problems, the instant disclosure employs an inventive converting material different from the phosphor combination used in the prior art in a photoelectric semiconductor device, the converting material can be excited by a UV to blue spectrum light emitting chip and has a first wavelength converting compound and a second wavelength converting compound both having specific full width at half maximum in the emission spectrum.

By employing the first wavelength converting compound and a second wavelength converting compound having specific full width at half maximum in the emission spectrum, the photoelectric semiconductor device provided by the instant disclosure can maintain excellent brightness while enhancing the NTSC value. In addition, by further covering a hard encapsulant having moisture-permeable resistance on the light emitting chip and arranging a protective layer on at least one of the substrate and the encapsulant, the reliability of the photoelectric semiconductor device can be further ensured.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1A is a schematic view of the photoelectric semiconductor device provided by one of the embodiments of the instant disclosure.

FIG. 1B is another schematic view of the photoelectric semiconductor device provided by one of the embodiments of the instant disclosure.

FIG. 2 is a schematic view of the photoelectric semiconductor device provided by another embodiment of the instant disclosure.

FIG. 3A is a schematic view of the photoelectric semiconductor device provided by yet another embodiment of the instant disclosure.

FIG. 3B is another schematic view of the photoelectric semiconductor device provided by yet another embodiment of the instant disclosure.

FIG. 4A is a schematic view of the photoelectric semiconductor device provided by still another embodiment of the instant disclosure.

FIG. 4B is another schematic view of the photoelectric semiconductor device provided by still another embodiment of the instant disclosure.

FIGS. 5A and 5B are the excitation spectrum and the emission spectrum of the first wavelength converting compound employed in the photoelectric semiconductor device provided by the embodiments of the instant disclosure respectively.

FIGS. 6A and 6B are the excitation spectrum and the emission spectrum of the second wavelength converting compound employed in the photoelectric semiconductor device provided by the embodiments of the instant disclosure respectively.

FIGS. 7 to 9 are the emission spectrums measured by employing a first converting material, a second converting material and a third converting material in the photoelectric semiconductor device provided by the embodiments of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

In order to provide a photoelectric semiconductor device with high NTSC and high brightness, the instant disclosure introduces green sulfide phosphors in combination with red phosphors having narrower full width at half maximum. The photoelectric semiconductor device provided by the instant disclosure has a brightness higher than 70% and a NTSC value higher than 85%.

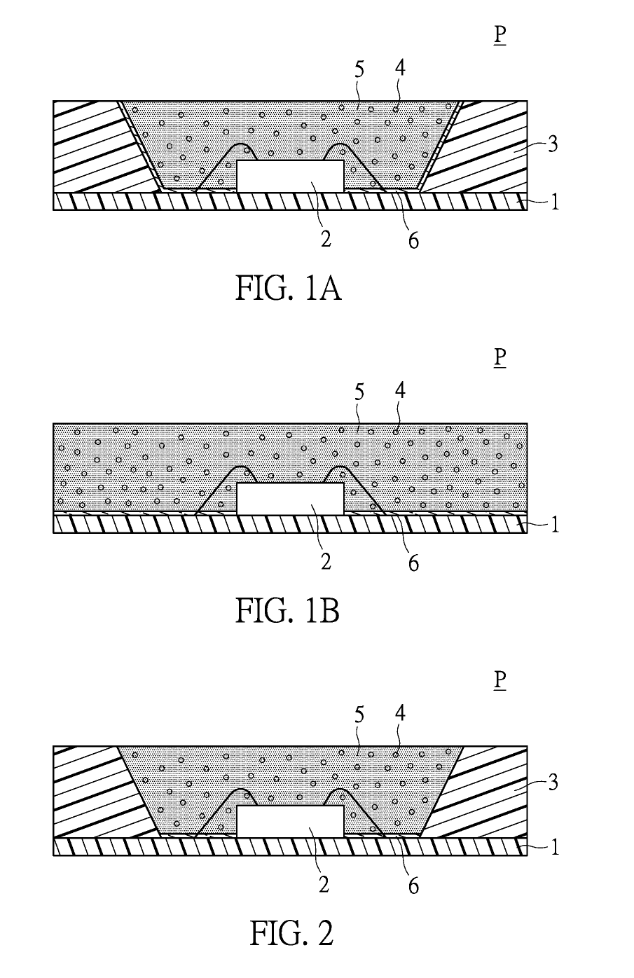

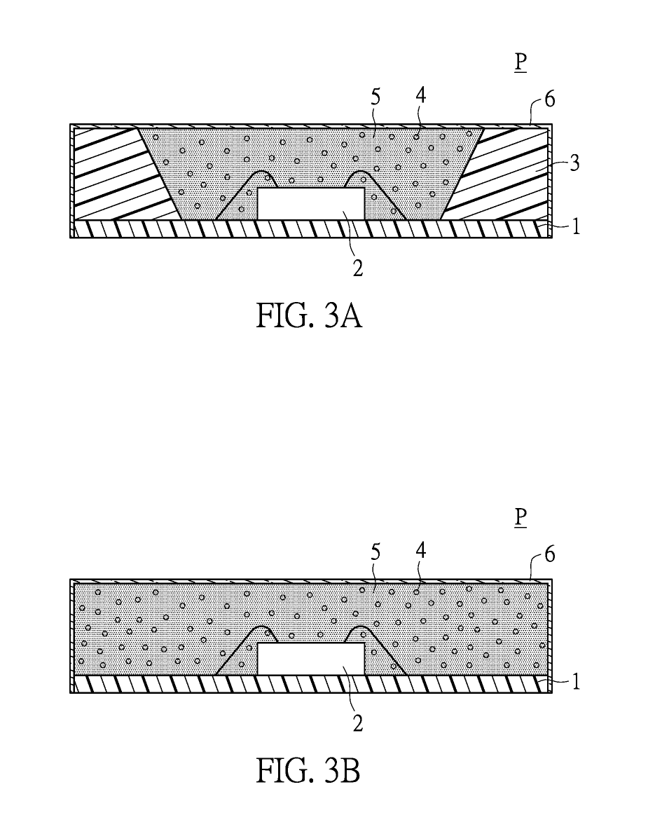

Please refer to FIG. 1A to FIG. 4B, the schematic views of the structures of the photoelectric semiconductor device provided by the embodiments of the instant disclosure. Specifically, FIG. 1A to FIG. 4B show the different implementations of the photoelectric semiconductor device provided by the embodiments of the instant disclosure.

As shown in FIG. 1A to FIG. 4B, the photoelectric semiconductor device P provided by the embodiments of the instant disclosure comprises a substrate 1, at least a light emitting chip 2, a converting material 4, an encapsulant 5 and a protective layer 6. The light emitting chip 2 is arranged on the substrate. The converting material 4 is arranged on the optical path of the light emitting chip 2, and the encapsulant 5 covers the light emitting chip 2. The protective layer 6 is arranged on at least one of the substrate 1, the converting material 4 and the encapsulant 5. In addition, as shown in FIGS. 1A, 2, 3A and 4A, the photoelectric semiconductor device P provided by the embodiments of the instant disclosure may further comprise a reflector 3 arranged on the substrate 1 and surrounding the light emitting diode 2. The details regarding the positions of the converting material 4 and the protective layer 6 will be described later.

The substrate 1 is made from any materials that can provide electrical connection to the light emitting chip 2. For example, the substrate 1 is an insulation substrate, a conductive substrate, a semiconductor substrate or a transparent substrate such as a substrate made from glass. In the instant disclosure, the number of the light emitting chip 2 is not limited, and the emission wavelength of the light emitting chip 2 is selected based on the requirements of the product or according to the properties of the converting material 4. For example, the light emitting chip 2 emits light having a wavelength of from 300 to 500 nanometers. In the embodiments of the instant disclosure, the light emitting chip 2 is a blue light chip and has an emission wavelength with the main peak of from 430 to 480 nanometers. The reflector 3 can be formed by materials such as metal, resin or glass, and a coating is optionally coated on the surface of the reflector 3 for increasing the light extraction efficiency of the photoelectric semiconductor device P or eliminating glazes. In one embodiment, the substrate 1 and the reflector 3 are integrally formed by a same material, thereby forming a cup-like housing.

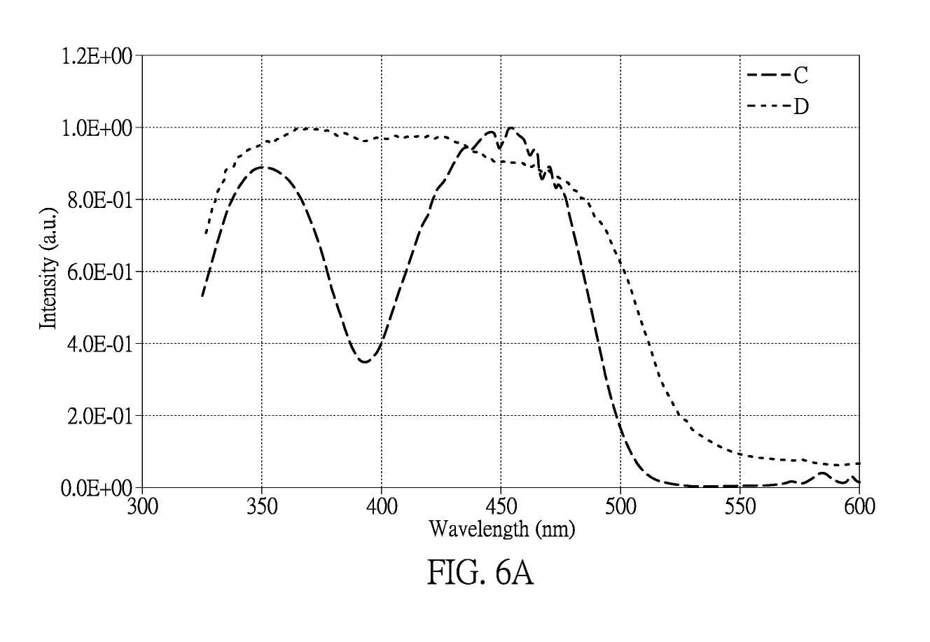

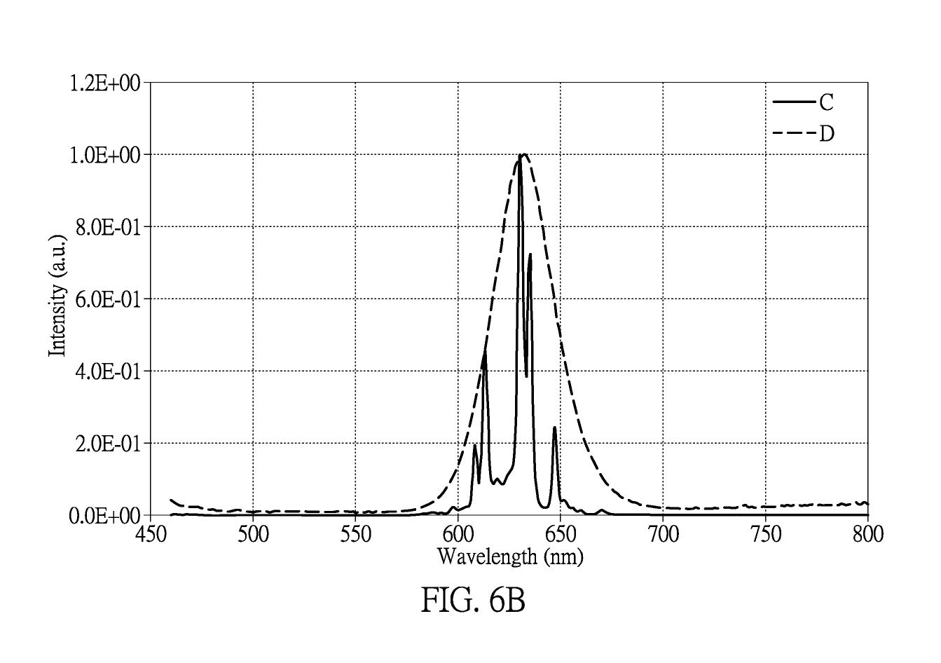

In the embodiments of the instant disclosure, the converting material 4 is arranged on the optical path of the light emitting chip 2 and is excited by the light emitted by the light emitting chip 2 for emitting light with a converted wavelength. For example, the converting material 4 is arranged on the light emitting chip 2 by dispensing, molding, printing, spraying or film-coating. As shown in FIG. 1A to FIG. 3B, the converting material 4 is mixed with the encapsulant 5 and covers the light emitting chip 2. When the photoelectric semiconductor device P comprises a reflector 3, the mixture of the converting material 4 and the encapsulant 5 fills the space formed by the reflector 3. Alternatively, the converting material 4 is arranged above the light emitting chip 2 as a sheet as shown in FIG. 4A and FIG. 4B. In another embodiment, the converting material 4 directly covers the light emitting chip 2, and the encapsulant 5 is arranged on the converting material 4 (not shown). In yet another embodiment, the converting material 4 is a laminate structure in which the lower layer contains the green phosphor and the upper layer contains the red phosphor.

In the embodiments of the instant disclosure, the converting material 4 (which is a wavelength converting material) comprises a first wavelength converting compound and a second wavelength converting compound.

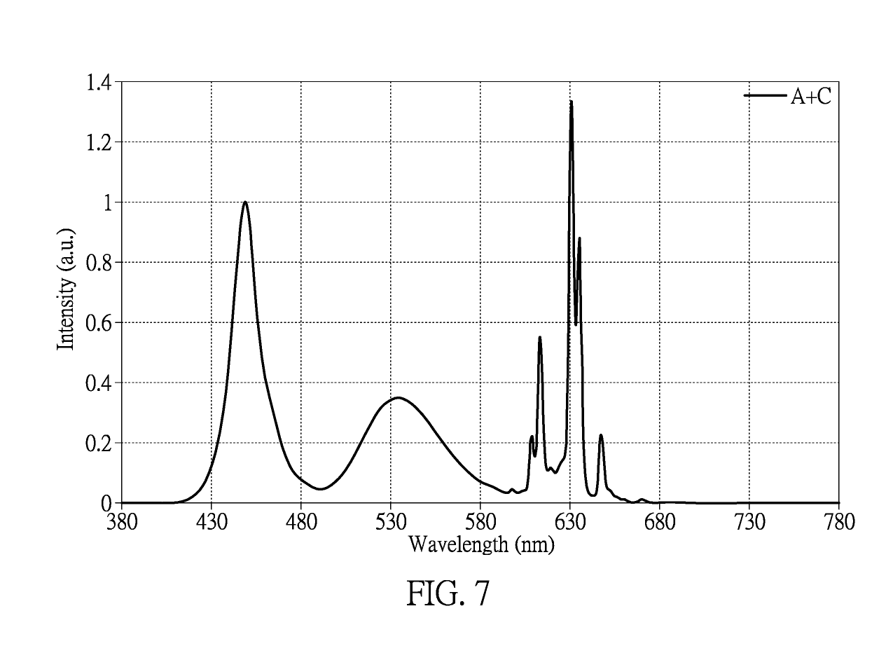

The first wavelength converting compound is excited by light having specific wavelength emitted by the light emitting chip 2, and emits light having a wavelength of from 525 to 535 nanometers. In other words, the first wavelength converting compound can be excited by light emitted by the light emitting chip 2 with short spectrum, such as UV and blue, and then emits light having a main peak in the green spectrum. Please refer to FIG. 5A, showing the excitation spectrum measured by the fluorescence spectrometer upon exciting the first wavelength converting compound with a specific light source (such as a light source having a wavelength of from 440 to 460 nanometers). As shown in FIG. 5A, the first wavelength converting compounds can be excited by light of from about 300 to 500 nanometers. The fluorescent material A represents an inorganic sulfide which can be effectively and continuously excited by light of from about 390 to 490 nanometers. The fluorescent material B represents a core-shell quantum dots (QD) which can be effectively and continuously excited by light of from about 310 to 475 nanometers.

FIG. 5B is an emission spectrum measured by the fluorescence spectrometer upon exciting the first wavelength converting compound with a light source having a selected wavelength. The first wavelength converting compound is a fluorescent material having a main peak wavelength in the green spectrum and a full width at half maximum of ≦50 nanometer. For example, the fluorescent material is an inorganic sulfide such as Sr₂GaS₄:Eu²⁺, or a core-shell quantum dot having an emission wavelength of from 515 to 550 nanometers. The core-shell quantum dot is a quantum dot comprising a semiconductor material of III-V group, II-VI group or (cadmium, manganese) selenium-based quantum dots, such as CdSe/Zn, ZnSe, CdS, MnSe/ZnSe, CdSe/ZnS, InP/ZnS, PbSe/PbS, CdSe/CdS, CdTe/CdS, CdTe/ZnS or cadmium free quantum dots. In addition, the quantum dots having a main peak in the green spectrum preferably have a particle diameter of from 0 to 30 nanometers. As shown in FIG. 5B, the inorganic sulfide (fluorescent material A) and the core-shell quantum dot (fluorescent material B) have emission peaks at about 535 nanometers and 532 nanometers respectively, and each has a full width at half maximum of 50 nanometers and 40 nanometers respectively.

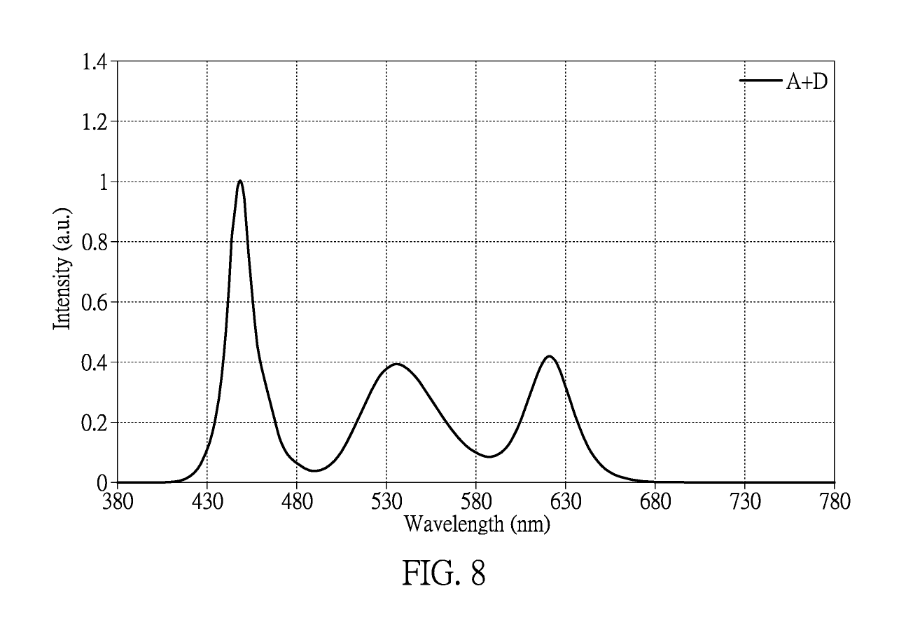

In the embodiments of the instant disclosure, the second wavelength converting compound is majorly excited by light of another specific wavelength and emits light having a wavelength of from 600 to 660 nanometers. In other words, the second wavelength converting compound emits light having a main peak in the red spectrum upon being excited. The second wavelength converting compound can be excited by the light emitted by the light emitting chip 2, the first wavelength converting compound, or combined thereof. Please refer to FIG. 6A showing the excitation spectrum of the second wavelength converting compound measured by the fluorescence spectrometer upon being excited by a specific light source. As shown in FIG. 6A, the second wavelength converting compound having a main peak in the red spectrum (the KSF (potassium flurorosilicate) phosphor emitting red light represented by C and the core-shell quantum dot emitting red light represented by D) can be excited by light having a wavelength of from 350 to 500 nanometers. The fluorosilicate phosphor represented by fluorescent material C can be effectively and continuously excited in the range of from about 400 to 500 nanometers, and the core-shell quantum dot represented by fluorescent material D can be effectively and continuously excited in the range of from about 330 to 520 nanometers.

The second wavelength converting compound having a main peak in the red spectrum (such as from 600 to 660 nanometer) is a fluorescent material having a full width at half maximum of ≦5 nanometers, such as a fluorosilicate phosphor (KSF phosphor, K₂SiF₆:Mn⁴⁺) or a fluorotitanate phosphor (KTF phosphor, K₂TiF₆:Mn⁴⁺). Alternatively, the fluorescent material is a core-shell quantum dot having a particle diameter of from 5 to 50 nanometers, such as III-V group, II-VI group or (cadmium, manganese) selenium-based semiconductor material, such as CdSe/Zn, ZnSe, CdS, MnSe/ZnSe, CdSe/ZnS, InP/ZnS, PbSe/PbS, CdSe/CdS, CdTe/CdS, CdTe/ZnS or cadmium free quantum dots.

Please refer to FIG. 6B. FIG. 6B shows the emission spectrum of the fluorescent materials having a main peak at the red spectrum, i.e., the fluorosilicate phosphor and the core-shell quantum dot. In FIG. 6B, the emission spectrum of the fluorosilicate phosphor is represented by the solid line C, and the emission spectrum of the core-shell quantum dot is represented by the dash line D. As shown in FIG. 6B, the emission peak of the fluorosilicate phosphor is at about 630 nanometers and has a full width at half maximum of about 5 nanometer, and the emission peak of the core-shell quantum dot fluorescent material is at about 628 nanometer and has a full width at half maximum of about 35 nanometers.

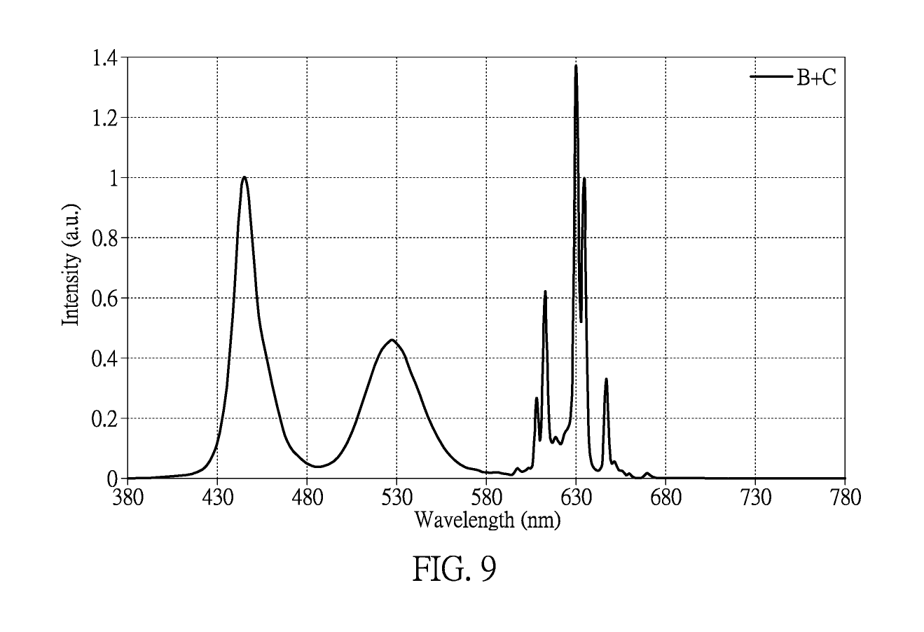

Please refer to FIG. 7 to FIG. 9. FIG. 7 is the emission spectrum of the photoelectric semiconductor device P provided by the embodiments of the instant disclosure measured by using a first converting material, FIG. 8 is the emission spectrum of the photoelectric semiconductor device P provided by the embodiments of the instant disclosure measured by using a second converting material, and FIG. 9 is the emission spectrum of the photoelectric semiconductor device P provided by the embodiments of the instant disclosure measured by using a third converting material.

FIG. 7 involves the use of the converting material 4 comprising the inorganic sulfide (fluorescent material A) as the first wavelength converting compound and the fluorosilicate (fluorescent material C) as the second wavelength converting compound, FIG. 8 involves the use of the converting material 4 comprising the inorganic sulfide (fluorescent material A) as the first wavelength converting compound and the core-shell quantum dot which is able to emit red light (fluorescent material D) as the second wavelength converting compound, and FIG. 9 involves the use of the converting material 4 comprising the core-shell quantum dot which is able to emit green light (fluorescent material B) as the first wavelength converting compound and the fluorosilicate (fluorescent material C) as the second converting material.

Next, please refer to FIGS. 1A to 4B again. In order to ensure the reliability of the photoelectric semiconductor device P of the embodiments of the instant disclosure, the instant disclosure further employs an encapsulant 5 and a protective layer 6. As mentioned before, the encapsulant 5 covers the light emitting chip 2, and if the photoelectric semiconductor device P comprises a reflector 3, the encapsulant 5 fills the space formed by the reflector 3. In addition, for enhancing the ability of weather resistance and lowering the influence of the application environment, the characteristics of the encapsulant 5 is the most important factor which should be taken care of. One of the characteristics is hardness, i.e., the shore hardness of the encapsulant 5 should be higher than D50, preferably higher than D55. Another characteristic is the anti-moisture property, i.e., the moisture-permeable value of the encapsulant 5 is less than 10 g/m²·24 hrs, preferably less than 8 g/m²·24 hrs. Therefore, such encapsulant 5 with at least one characteristics of higher hardness and less moisture-permeable property is able to effectively protect the components inside of the photoelectric semiconductor device P from outside containments, such as toxic material in the application environment, and prevent water from entering the photoelectric semiconductor device P.

In the embodiments of the instant disclosure, the encapsulant 5 can be made from silicon resin or epoxy resin. If the encapsulant 5 is made from an epoxy resin, the benzene ring or other cyclic structures in the polymer structure may render higher hardness of the epoxy resin. The example of the epoxy resin includes epoxy resins formed by bisphenol-A diglycidyl ether (BADGE), cycloaliphatic epoxy resin, methylhexahydrophthalic anhydride (MHHPA) or cyclohexanedicarboxylic anhydride (HHPA) or the combination thereof. The silicone resins employed by the embodiments of the instant disclosure are silicone resins having relatively more phenyl structure (high phenyl content) or silicone resins having high crosslink density. In other words, silicone resins including more T structure (MeSiO₃) or Q structure (SiO₄) in the polymer chain would have higher hardness and moisture-permeable value and are more suitable for forming the encapsulant 5.

Please refer to FIG. 1A to FIG. 4B. In the embodiments of the instant disclosure, the protective layer 6 can be arranged on one or more of the substrate 1, the reflector 3, the converting material 4 and the encapsulant 5. Specifically, the protective layer 6 is used for preventing damage caused by the contaminants outside or inside of the photoelectric semiconductor device P. An example of outside contaminants comprises toxic gas in the air, corrosive chemicals in the rain such as sulfides, or the chemicals comprised in the packaging of the product. In the instant disclosure, the protective layer 6 is an anti-sulfur layer arranged on the substrate 1 and/or the reflector, a white silicone coating arranged on the substrate, or a fluorine-containing layer arranged on the reflector 3, the converting material 4 or the encapsulant 5.

Please refer to FIGS. 1A and 1B. In this embodiment, the protective layer 6 is an anti-sulfur layer arranged on the substrate 1, or an anti-sulfur layer arranged on both of the substrate 1 and the reflector 3. The anti-sulfur layer may be an anti-sulfur barrier which is coated on the silver-coatings for preventing the sulfur ions in the environment from reacting with the silver affecting the effectiveness of the wires. As shown in FIG. 1A, the protective layer 6 forms a continuous coating which covers the surface of the substrate 1 and the surface of the reflector 3. Alternatively, as shown in FIG. 1B, the protective layer 6 forms a continuous surface on the surface of the substrate 1, i.e., the protective layer 6 completely covers the surface of the substrate 1. The anti-sulfur layer is made from silicone resin, acrylic resin or fluorine-containing compounds. For example, the anti-sulfur layer is formed by dissolving acrylic polymer in an organic solvent such as ethyl acetate or toluene for forming a coating solution. The process for forming the anti-sulfur layer from the coating solution may comprise impregnating, coating, spraying or dispensing processes. In addition, the thickness of the anti-sulfur layer is from 0 to 5 micrometer (μm). However, the actual thickness of the anti-sulfur layer can be selected according to the need of the product and is not limited thereto.

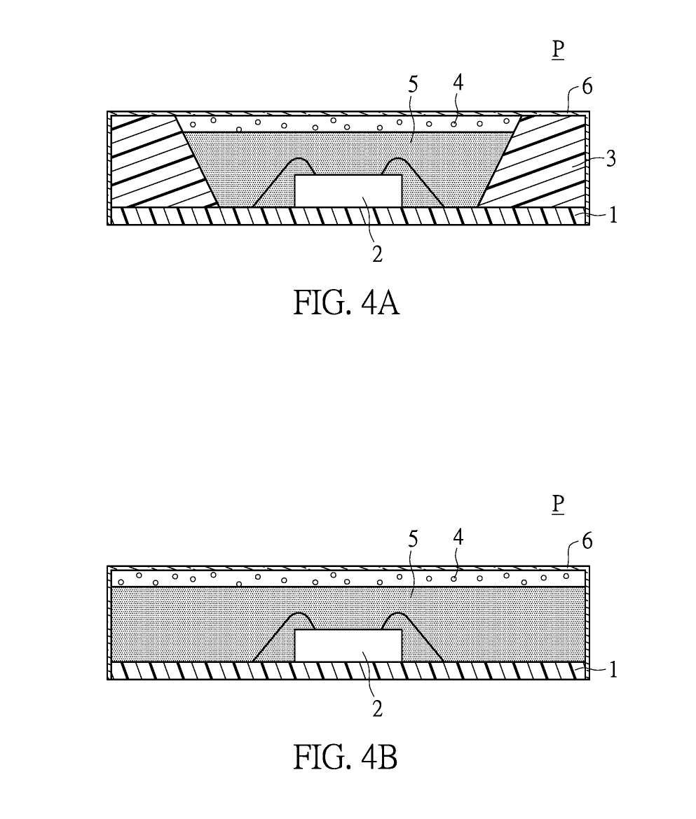

Please refer to FIG. 2. In this embodiment, the protective layer 6 is a white silicone resin coating arranged on the substrate 1. Similar to the anti-sulfur layer mentioned before, the white silicone resin coating can be coated on the silver-containing wires as an anti-sulfur barrier for preventing the sulfur ion in the environment from reacting with the silver thereby affecting the effectiveness of the wires. The white silicone resin coating can be formed by thermoset white silicone resins and transparent silicone resins having high transmittance. Preferably, the white silicone resin coating is formed by a silicone resin having excellent light and heat stability and hence, the light extracting efficiency, the overall power efficiency and the reliability of the photoelectric semiconductor device P is enhanced. In addition, the thickness of the white silicone resin coating may be from 50 to 150 micrometer (μm).

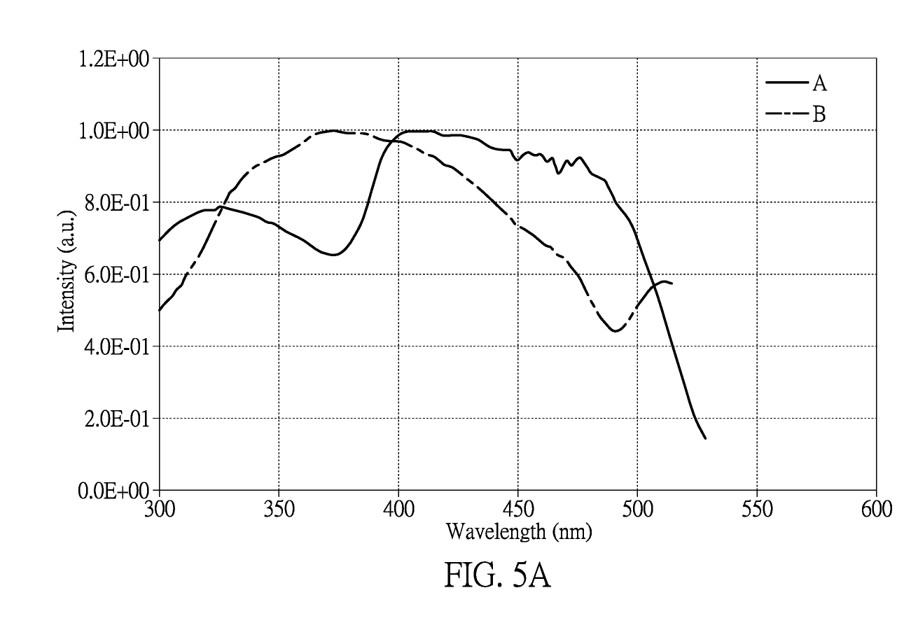

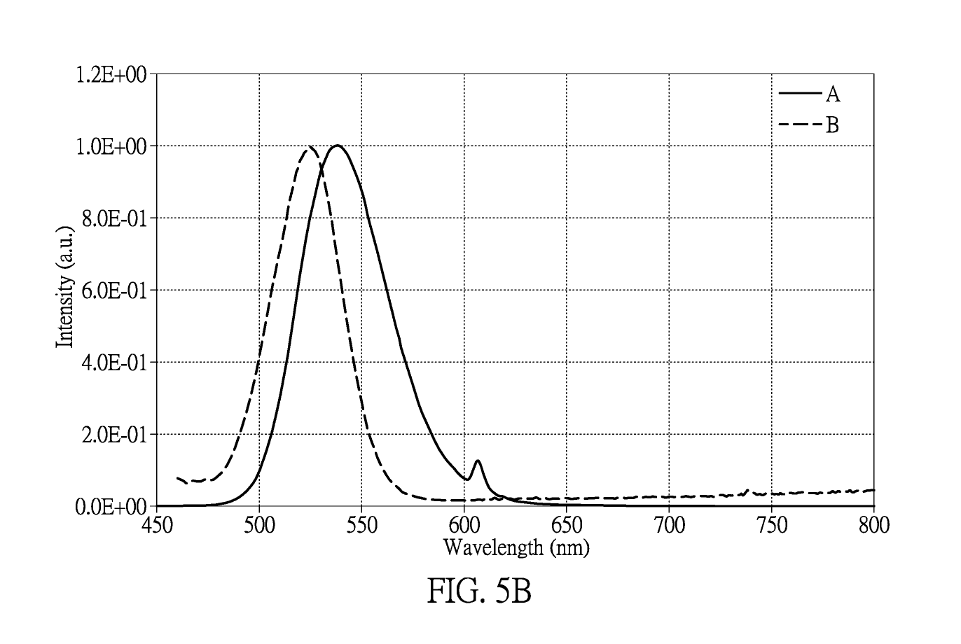

Please refer to FIGS. 3A and 3B. In this embodiment, the protective layer 6 is a fluorine-containing layer surrounding the encapsulant 5, or a fluorine-containing layer surrounding both of the reflector 3 and the encapsulant 5. The protective layer 6 encapsulates and isolates the encapsulant 5 (and the reflector 3) from the outside contaminants, preventing the inner components from being damaged by the outside contaminants. For example, the fluorine-containing layer is formed by fluorine-containing silicone resin with high transmittance.

Please refer to FIGS. 4A and 4B. When the converting material 4 is arranged above the light emitting chip 2 as a sheet, i.e., the converting material 4 is presented as a mixture of the converting material 4 and the encapsulant 5, the protective layer may be a fluorine-containing layer surrounding the converting material 4 and the encapsulant 5, or a fluorine-containing layer surrounding the converting material 4 and the reflector 3. The encapsulant 5 without the converting material 4 directly covers the light emitting chip 2 and isolates the substrate 1 and the light emitting chip 2 to keep it from directly contacting with the converting material 4. Therefore, certain fluorescent materials (such as the fluorine-containing compound) are not able to react with the inner components of the photoelectric semiconductor device P. The protective layer 6 covering the converting material 4 and the encapsulant 5 (or the converting material 4 and the reflector 3) is for isolating the outside contaminants and preventing the inner components from being damaged by the outside contaminants.

The effectiveness achieved by the photoelectric semiconductor device P of the embodiments of the instant disclosure is described in the examples below.

### EFFECTIVENESS OF THE EMBODIMENTS

### A. Optical Properties of the Photoelectric Semiconductor Device

Please refer to Table 1. Table 1 shows the NTSC value and the brightness (lm/W ratio) of the photoelectric semiconductor device P employing different converting materials 4. Table 1 also shows the full width at half maximum in the emission spectrum of the different first wavelength converting compounds and the second wavelength converting compounds.

In table 1, Y1 represents a yellow phosphor, R1˜RS represent red phosphors or red core-shell quantum dots, and G1˜G3 represent green phosphors or green core-shell quantum dots. The values in the parentheses are the emission peak value (in nanometer) of the first wavelength converting compounds and the second wavelength converting compounds. The NTSC values are calculated by the x and y axes colorimetric values (Cx, Cy) of red (R), green (G) and blue (B) color points.

### Comparative Examples 1 to 4

In the comparative example 1, the first wavelength converting compound is a yellow phosphor (Y1) having a full width at half maximum of 121 nanometers, and the second wavelength converting compound is a red phosphor (R1) having a full width at half maximum of 75 nanometers. The above phosphor combination achieves an NTSC value of 71.80% and a brightness of 100%.

In the comparative example 2, the first wavelength converting compound is a green phosphor (G1) having a full width at half maximum of 71 nanometers, and the second wavelength converting compound is a red phosphor (R2) having a full width at half maximum of 92 nanometers. The above phosphor combination achieves an NTSC value of 78.10%. However, compared to comparative example 1, the brightness is reduced to 82.10%.

The first wavelength converting compounds employed in the comparative examples 3 and 4 are green phosphors (G2) and (G3) having a full width at half maximum of 54 nanometers, and the second wavelength converting compound employed in the comparative examples 3 and 4 are red phosphors (R2) and (R3) having a full width at half maximum of 92 nanometers. The converting materials of the comparative examples 3 and 4 achieve NTSC values of 82.30% and 84.90% and brightness of 76% and 64.7% respectively.

### Examples 1 to 4

Example 1 employs a green core-shell quantum dot (G4) having a full width at half maximum of 40 nanometers as the first wavelength converting compound, and a red core-shell quantum dot (R4) having a full width at half maximum of 35 nanometers as the second wavelength converting compound. Example 1 achieves an NTSC value of 98.30% and a brightness of 73.5%.

Example 2 employs a sulfide (G5) having a full width at half maximum of 50 nanometers as the first wavelength converting compound, and a red core-shell quantum dot (R4) having a full width at half maximum of 35 nanometers as the second wavelength converting compound. Example 2 achieves an NTSC value of 87.4% and a brightness of 86.9%.

Example 3 employs a green core-shell quantum dot (G4) having a full width at half maximum of 40 nanometers as the first wavelength converting compound, and a KSF (R5) having a full width at half maximum of 5 nanometers as the second wavelength converting compound. Compared to example 2 which employs the red core-shell quantum dot (R4) having a full width at half maximum of 35 nanometers, the brightness of the example 3 decreases from 86.9% to 78.3%. However, the NTSC value significantly increases from 87.4% to 101.9%.

Example 4 employs a sulfide (G5) having a full width at half maximum of 50 nanometers as the first wavelength converting compound, and KSF (R5) having a full width at half maximum of 5 nanometers as the second wavelength converting compound. Example 4 achieves an NTSC value of 92.43% and a brightness of 90.5%.

Accordingly, the converting materials employed in the examples 1 to 4 of the instant disclosure exhibit an enhanced NTSC value while ensuring excellent brightness. In other words, compared to the comparative examples 1 to 4 in which the brightness significantly decreases while increasing the NTSC values, the converting materials of examples 1 to 4 of the instant disclosure achieve both high NTSC value and high brightness.

In summary, as shown in Table 1, compared to the comparative examples employing conventional phosphors as converting materials, the first wavelength converting compounds and the second wavelength converting compounds having specific full width at half maximum would increase the NTSC value of the photoelectric semiconductor device P to above 85%, and maintain the brightness of the photoelectric semiconductor device P at above 70%.

### B. Reliability of the Photoelectric Semiconductor Device

### (1) Anti-Sulfur Test

Table 2 shows the materials employed in the anti-sulfur test and the results obtained therefrom. The details of the anti-sulfur test are described below.

TABLE 2

| | | shore | type | |
|---|---|---|---|---|
| | type | hardness | of the | remain |
| | of the | of the | protective | brightness |
| | encapsulant | encapsulant | layer | (lm %) |
| comparative | silicone | D29 | none | 67.26 |
| example 5 | resin | | | |
| example 5-1 | silicone | D67 | none | 98.83 |
| | resin | | | |
| example 5-2 | silicone | D55 | none | 98.44 |
| | resin | | | |
| example 6-1 | silicone | D29 | anti-sulfur | 98.41 |
| | resin | | layer | |
| example 6-2 | | | fluorine- | 98.02 |
| | | | containing | |
| | | | polymer | |
| example 6-3 | | | acrylic resin | 84.62 |
| example 7 | | | white | 87.41 |
| | | | silicone | |
| | | | resin | |
| example 8 | | | fluorine- | 86.85 |
| | | | containing | |
| | | | polymer | |

### A. Encapsulant

In Comparative example 5, a silicone resin having a shore hardness of D29 and a moisture-permeable value of 15 g/m²·24 hrs is used as the encapsulant 5 covering the light emitting chip 2 of the photoelectric semiconductor device P. The photoelectric semiconductor device P is arranged in a sulfur-containing environment. The luminous energy (Lm) of the photoelectric semiconductor device P is measured and shows a remain Lm of 67.26%.

In Example 5-1, the same process employed in Comparative example 5 is conducted for performing the anti-sulfur test. The difference between Comparative example 5 and Example 5-1 is that a gas barrier hard encapsulant having high hardness and moisture-permeable resistance is used as the encapsulant 5 for substituting the silicone resin used in the comparative example. In Example 5-1, the silicone resin used as the encapsulant 5 has a shore hardness of D67 and a moisture-permeable value of 8 g/m2.24 hrs. The result shows a remain Lm of 98.83%.

In Example 5-2, the same process employed in Comparative example 5 is conducted for performing the anti-sulfur test. The difference between Comparative example 5 and Example 5-2 is that a silicone resin having a shore hardness of D55 is used as the encapsulant 5. The result shows a remain Lm of 98.44%.

B. Protective layer

Example 6-1 employs the silicone resin used in the comparative example as the encapsulant 5, and employs an anti-sulfur layer on the substrate 1 of the photoelectric semiconductor device P as the protective layer 6. The photoelectric semiconductor device P is arranged in a sulfur-containing environment, and the luminous energy (Lm) of the photoelectric semiconductor device P is measured and shows a remain Lm of 98.41%.

Example 6-2 employs the same testing process of Example 6-1, only substitutes the anti-sulfur layer with a fluorine-containing polymer. The result shows a remain Lm of 98.02%.

Example 6-3 employs the same testing process of Example 6-1 and use an anti-sulfur layer of an acrylic resin as the protective layer 6. The result shows a remain Lm of 84.65%.

In Example 7, the silicone resin used in the comparative example is used as the encapsulant 5, and a white silicone resin coating is used as the protective layer 6 arranging on the substrate 1 and the reflector 3 of the photoelectric semiconductor device P. The photoelectric semiconductor device P is arranged in a sulfur-containing environment. The luminous energy (Lm) of the photoelectric semiconductor device P shows a remain Lm of 87.41%.

In Example 8, the silicone resin used in the comparative example is used as the encapsulant 5, and the fluorine-containing polymer used in Example 6-2 is used as the protective layer 6 arranged on the substrate 1 and the reflector 3 of the photoelectric semiconductor device P. the photoelectric semiconductor device P is arranged in a sulfur-containing environment. The luminous energy (Lm) of the photoelectric semiconductor device P shows a remain Lm of 86.85%.

Based on the results of the anti-sulfur tests of the photoelectric semiconductor device P above, it is shown that the encapsulant 5 having a specific shore hardness and moisture-permeable value, and the protective layer 6 would improve the anti-sulfur property of the photoelectric semiconductor device P. Specifically, compared to Comparative example 5 employing the silicone resin having a shore hardness of D29 as the encapsulant 5 and without any protective layer, the remain Lm of the photoelectric semiconductor devices P of Examples 5-1 to 8 is increased from 67.26% to above 84.65%.

### (2) Reliability Test

The reliability test is performed on the photoelectric semiconductor device P by using soft encapsulant and hard encapsulant as encapsulant 5. First, after covering a soft encapsulant having a shore hardness of less than D50 and a hard encapsulant having a shore hardness of larger than D50 on two photoelectric semiconductor devices P of the same type, the reliability test is conducted under the condition of 60° C./90% R.H. and 150 mA. After 3000 hours, the remain Lm of the photoelectric semiconductor device P employing the hard encapsulant as the encapsulant 5 is 2.9% higher than the remain Lm of the photoelectric semiconductor device P employing the soft encapsulant as the encapsulant 5.

Next, conducting the reliability test on another two photoelectric semiconductor devices P of the same type employing a soft encapsulant having a shore hardness of less than D50 and a hard encapsulant having a shore hardness of larger than D50 respectively under the condition of 60° C./90% R.H. and 120 mA. After 3000 hours, the remain Lm of the photoelectric semiconductor device P employing the hard encapsulant as the encapsulant 5 is 5.6% higher than the remain Lm of the photoelectric semiconductor device P employing the soft encapsulant as the encapsulant 5.

Based on the results of the reliability test, it is confirmed that using a hard encapsulant having a shore hardness larger than D50 as the encapsulant 5 can effectively increase the reliability of the photoelectric semiconductor device P.

In summary, the advantages of the instant disclosure resides in that by using the converting material 4 having wavelength converting compounds with specific full width at half maximum in the emission spectrum, the photoelectric semiconductor device P provided by the embodiments of the instant disclosure has improved NTSC and brightness. Moreover, by further employing an encapsulant 5 and a protective layer 6 with specific shore hardness or moisture-permeable value, the reliability of the photoelectric semiconductor device P using the above converting material 4 is further ensured.

The above-mentioned descriptions represent merely the exemplary embodiment of the present disclosure, without any intention to limit the scope of the instant disclosure thereto. Various equivalent changes, alterations or modifications based on the claims of the instant disclosure are all consequently viewed as being embraced by the scope of the instant disclosure.

What is claimed is:

1. A photoelectric semiconductor device, comprising:
a substrate;
at least a light emitting chip arranged on the substrate;
a converting material arranged on an optical path of the light emitting chip;
an encapsulant covering the light emitting chip, the encapsulant has a Shore hardness higher than D50 or a moisture-permeable value of less than 10 g/m²·24 hrs; and
a protective layer arranged on at least one of the substrate and the encapsulant;
wherein the converting material comprises a first wavelength converting compound having a main peak wavelength in green spectrum and a second wavelength converting compound having a main peak wavelength in red spectrum, the first wavelength converting compound and the second wavelength converting compound are both fluorescent materials having a full width at half maximum of equal or less than 50 nm.

2. The photoelectric semiconductor device according to claim 1, wherein the encapsulant is positioned between the converting material and the light emitting chip, or is a mixture comprising the converting material and directly covering the light emitting chip.

3. The photoelectric semiconductor device according to claim 2, further comprising a reflector arranged on the substrate and surrounding the light emitting chip.

4. The photoelectric semiconductor device according to claim 3, wherein the protective layer is an anti-sulfur coating arranged on at least one of the substrate and the reflector.

5. The photoelectric semiconductor device according to claim 4, wherein the anti-sulfur coating is made from acrylic resin or silicone resin.

6. The photoelectric semiconductor device according to claim 3, wherein the protective layer is a fluorine-containing layer surrounding at least one of the reflector, the encapsulant, the converting material and the mixture.

7. The photoelectric semiconductor device according to claim 1, wherein the first converting material is an inorganic sulfide or a core-shell quantum dot of a group III-V, group II-VI or manganese-selenium semiconductor material having a diameter of from 0 to 30 nanometers.

8. The photoelectric semiconductor device according to claim 7, wherein the second converting material is a fluorescent material having a full width at half maximum in emission spectrum of less or equal to 5 nanometers, or a core-shell quantum dot of a group III-V, group II-VI or manganese-selenium semiconductor material having a diameter of from 0 to 50 nanometers.

9. The photoelectric semiconductor device according to claim 1, wherein the second converting material is a fluorescent material having a full width at half maximum in emission spectrum of less or equal to 5 nanometers, or a core-shell quantum dot of a group III-V, group II-VI or manganese-selenium semiconductor material having a diameter of from 0 to 50 nanometer.

10. The photoelectric semiconductor device according to claim 1, wherein the encapsulant is a silicone resin with high phenyl group content or high crosslink density.

11. The photoelectric semiconductor device according to claim 1, wherein the encapsulant is an epoxy resin with a high content of phenyl group or other cyclic structures.

12. The photoelectric semiconductor device according to claim 1, wherein the encapsulant is selected from bisphenol-A diglycidyl ether (BADGE), cycloaliphatic epoxy resin, methylhexahydrophthalic anhydride (MHHPA) or cyclohexanedicarboxylic anhydride (HHPA) or the combination thereof.

13. The photoelectric semiconductor device according to claim 2, wherein the protective layer is an anti-sulfur layer arranged on the substrate.

14. The photoelectric semiconductor device according to claim 11, wherein the anti-sulfur layer is made from acrylic resin or silicone resin.

15. The photoelectric semiconductor device according to claim 11, wherein the protective layer is a fluorine-containing layer arranged on one of the encapsulant, the converting material and the mixture.
